(19) United States
(12) Patent Application Publication
(10) Pub. No.: US 2019/0081459 A1
(43) Pub. Date: Mar. 14, 2019

(54) POWER DISTRIBUTION BOX EQUIPPED WITH BUSBAR INTEGRATED ELECTRIC METER

(71) Applicant: TOZZTECH CO., LTD., Anyang-si (KR)

(72) Inventors: Hyeon Jin HA, Seoul (KR); Hak Su OH, Incheon (KR); Hyun Do LEE, Suwon-si (KR); Kook Wang NOH, Siheung-si (KR); Dong Woo KIM, Seoul (KR)

(21) Appl. No.: 16/117,651

(22) Filed: Aug. 30, 2018

(30) Foreign Application Priority Data
Sep. 8, 2017 (KR) 10-2017-0115287

(51) Int. Cl. H02B 1/20; H02B 1/03; H02B 1/48; H02B 1/04; G01R 22/06

(52) U.S. Cl. CPC H02B 1/20; H02B 1/03; G01R 22/061; H02B 1/04; H02B 1/48

(57) ABSTRACT

Provided is a power distribution box distributing commercial electric power supplied from lead-in electric power lines into branch electric power sources and supplying the branch electric power sources to respective loads connected thereto. A power distribution box equipped with a busbar integrated electric meter includes: a main circuit breaker connected to lead-in power supply lines to which commercial power is supplied; a plurality of branch circuit breakers connected to power supply branch lines connected to respective loads; busbars including lead-out bars drawn out from the main circuit breaker, and a plurality of lead-in bars branched out from the lead-out bars and entering into the plurality of branch circuit breakers, respectively; and an electric meter measuring a power applied to each of the plurality of branch circuit breakers through each of the lead-out bars of the busbars.

### BACKGROUND OF THE INVENTION

### Field of the Invention

The present invention relates to a power distribution box distributing commercial electric power supplied from lead-in electric power lines into branch electric power sources and supplying the branch electric power sources to respective loads connected thereto. More particularly, the present invention relates to a power distribution box equipped with a busbar integrated electric meter connecting a main circuit breaker and a plurality of branch circuit breakers by busbars and having an electric meter which measures power applied to each branch circuit breaker through busbars.

### Description of the Related Art

Electric power entering into a building is supplied to the inside of the building through a power distribution box, wherein the power distribution box supplied with a predetermined amount of power supplied from a switchboard is provided with switches for each branch circuit at a place where branch circuits are separated from the main lines in the indoor wiring. The power distribution box is a device by which the power supply is appropriately distributed to and blocked from various loads such as electric lighting, electric heating, electric power loads, and so on of houses, offices of buildings, or plants.

As shown in Korean Utility Model Registration No. 20-0431486 “Main circuit breaker for cabinet”, Korean Patent No. 10-1090558 “Distributing board,” Korean Patent No. 10-0779233 “Cabinet panel for distributing electric power”, and the like, the power distribution box includes: a main circuit breaker connected to lead-in power supply lines to which commercial power is supplied, a plurality of branch circuit breakers each connected to power supply branch lines providing branched power supply to respective loads, and an electric meter measuring a power consumed by electric loads through a panel board.

A power distribution box according to a conventional art connects the main circuit breaker and the branch circuit breakers using cables or busbars connected to the cables. Accordingly, a drawback is that the arrangement of the cables is inside a narrow enclosure, which is inconvenient.

In addition, the electric meter of the power distribution box according to the related art measures only the total power consumed through the power distribution box and does not separately measure the electric power consumed by each load.

Furthermore, in the related art, due to the narrow internal space of the enclosure, the main circuit breaker, the branch circuit breakers, the electric meter, and the like are difficult to be installed or to be disassembled for maintenance.

### SUMMARY OF THE INVENTION

Accordingly, the present invention has been made to solve above problems occurring in a power distribution box according to a conventional art, and the present invention is intended to propose a power distribution box equipped with a busbar integrated electric meter, wherein the power distribution box allows the connection work to be easy, and eliminates inconvenience in arranging the cables by directly connecting the main circuit breaker and the branch circuit breakers by busbars without using cables. In addition, the power distribution box is able to measure the power consumed by each load (for example, lighting, air conditioner, kitchen, first electric heater, or second electric heater) and analyze the power usage patterns for each branch line, thereby realizing efficient and specific energy management. Furthermore, the power distribution box allows the main circuit breaker, an electric meter, and the like to be easily and quickly installed to and disassembled from the enclosure.

In order to achieve the above object, the power distribution box equipped with the busbar integrated electric meter includes:

a main circuit breaker connected to lead-in power supply lines to which commercial power is supplied;

a plurality of branch circuit breakers connected to power supply branch lines connected to respective loads;

busbars including lead-out bars drawn out from the main circuit breaker, and a plurality of lead-in bars branched out from the lead-out bars and entering into the plurality of branch circuit breakers, respectively; and

an electric meter measuring power applied to each of the plurality of branch circuit breakers through each of the lead-in bars of the busbars.

In addition, the power distribution box further includes:

a bracket mounted with the main circuit breaker, the branch circuit breakers, and the electric meter;

a casing enclosing the bracket,

a door openably covering an opening of the casing; and

an enclosure including a transparent window provided on the door and allowing the inside of the casing to be seen through.

Furthermore, the power distribution box further includes:

an engaging plate provided on both sides of the bracket in the forward and backward directions;

an engaging block coupled to both side inner walls of the casing;

a guide groove formed in the front and rear directions on the surface of the engaging block and becoming deeper toward the rear;

an engaging ball moving along the guide groove;

a cover covering the engaging block; and

an engaging device that is operated such that when the engaging plate enters into a gap between the engaging block and the cover and moves rearward, the engaging ball is brought into contact with the engaging plate and pushed rearward along the guide groove, thereby allowing the engaging plate to advance, and when the engaging plate moves forward, the engaging ball brought into contact with the engaging plate moves forward along the guide groove, thereby allowing the engaging plate not to move backwards by pressing the surface of the engaging plate.

The power distribution box equipped with the busbar integrated electric meter according to the present invention allows connection work to be convenient by connecting the main circuit breaker and the branch circuit breakers only by the busbars and causes no inconvenience in arranging the cables.

In addition, the power distribution box allows the power consumed by each load to be measured separately and the power usage patterns for each branch lines to be analyzed, thereby enabling efficient energy management to be performed accordingly.

Furthermore, the main circuit breaker and the branch circuit breakers are mounted on a separate same bracket that can be easily and quickly assembled into or separated from the enclosure by an engaging device, whereby work such as installation and maintenance of the power distribution box is very convenient.

### BRIEF DESCRIPTION OF THE DRAWINGS

The above and other objects, features, and other advantages of the present invention will be more clearly understood from the following detailed description when taken in conjunction with the accompanying drawings, in which:

FIG. 1 is a block diagram of a power distribution box equipped with a busbar integrated electric meter according to an embodiment of the present invention;

FIG. 2 is a perspective view of a power distribution box equipped with a busbar integrated electric meter according to the present invention;

FIG. 3 is an exploded perspective view of FIG. 2;

FIG. 4 is a perspective view showing an engaging device as a main part; and

FIG. 5 is a view explaining a process in which the bracket and the casing are assembled or disassembled by the engaging device.

[Description of the Reference Numerals in the Drawings]

| | | | |
|---|---|---|---|
| 10: | Main circuit breaker | 20: | Branch circuit breaker |
| 30: | Busbar | 40: | Electric meter |
| 50: | Enclosure | 51: | Casing |
| 53: | Door | 57: | Bracket |
| 60: | Engaging device | 61: | Engaging plate |
| 62: | Engaging block | 63: | Guide groove |
| 64: | Engaging ball | 65: | Cover |
| 66: | Depth adjustment plate | 67: | Inclined block |

### DETAILED DESCRIPTION OF THE INVENTION

Hereinafter, a power distribution box equipped with a busbar integrated electric meter according to the present invention will be described in detail with reference to the drawings.

Prior to describing the power distribution box equipped with the busbar integrated electric meter of the present invention in more detail, as the present invention can be added with various modifications and have various forms, embodiments (or aspects) will be described in detail in the following text. It should be understood, however, that the invention is not intended to be limited to the particular forms disclosed, but includes all modifications, equivalents, and alternatives falling within the spirit and scope of the present invention.

In the drawings, the same reference numerals, particularly, same reference numerals which have the same tens digit and ones digit, or the same tens digit, ones digit, and letter are used as a representing member of a framework having the same or similar function. Unless otherwise noted, a member of framework referred to by each reference numeral may be identified as the member corresponding to this standard.

In addition, the components in each drawing may be expressed exaggeratingly larger (or thicker) or smaller (or thinner) in size or thickness, or by simplified structure thereof, in consideration of the convenience of understanding, but it should not be construed the scope of the protection of the present invention is limited thereby.

It is to be understood that the terms used in the present patent specification are for the purpose of describing only particular embodiments (or aspects) and are not intended to limit the present invention. An expression in a singular form includes an expression in a plural form, unless the meaning is not obviously different contextually.

It should be understood that terms such as “include” or “composed” in the present invention are intended to designate the existence of a characteristic, numeral, step, movement, constituent, parts, or combination of these and should be understood not to exclude in advance the existence or a possibility of addition of at least one of other characteristics, numerals, steps, movements, constituents, parts, or combination of these.

Unless otherwise defined, all terms used herein, including technical or scientific terms, have the same meaning as commonly understood by a person having ordinary knowledge in the art to which the present invention pertains. Terms such as those defined in commonly used dictionaries should be interpreted as having a meaning consistent with the meaning in the context of the relevant art and should not be interpreted as ideal or overly formal in meaning unless explicitly defined in the present application.

As shown in the drawings, the power distribution box equipped with the busbar integrated electric meter according to the present invention includes a main circuit breaker 10, branch circuit breakers 20, busbars 30, an electric meter 40, an enclosure 50, and an engaging device 60.

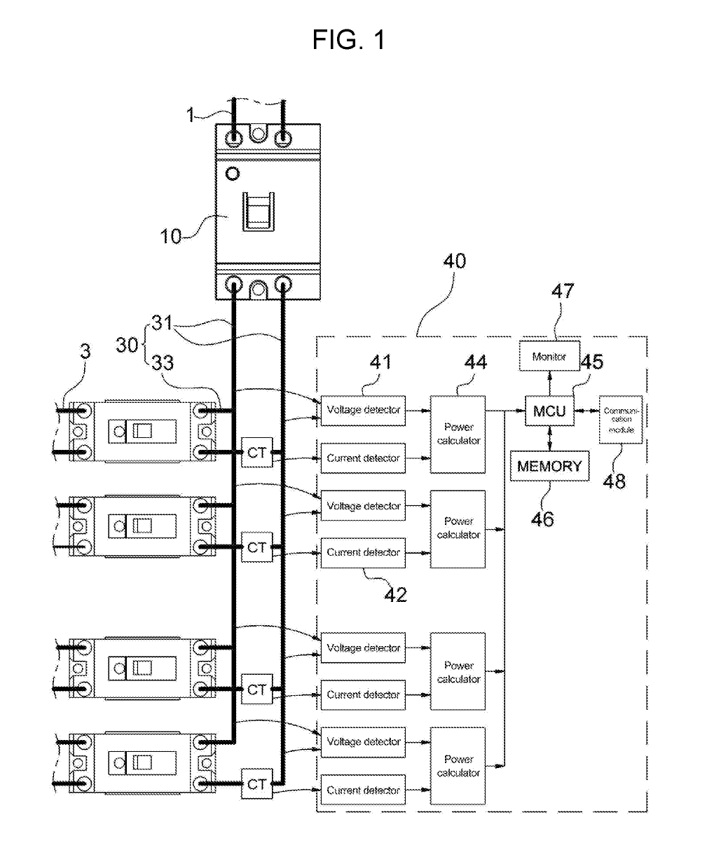

First, the electrical configuration of the power distribution box equipped with the busbar integrated electric meter according to the present invention illustrated in FIG. 1 will be described.

The main circuit breaker 10 receives commercial power through an input side thereof connected to input power supply lines 1 and applies the supplied commercial power through busbars 30 connected to an output side thereof to branch circuit breakers 20.

The main circuit breaker 10 prevents an electric accident by blocking the lead-in power supply lines 1 when overvoltage such as surge voltage is supplied through the lead-in power supply lines 1 or overload is applied to the load side.

The branch circuit breakers 20 supply power to the loads through the output sides thereof connected correspondingly to power supply branch lines 3, and receive power supply branched out from the busbars 30 through the input sides thereof connected correspondingly to lead-in bars 33 of the busbars 30.

The branch circuit breaker 20 prevents electric accidents by blocking the power supply branch lines 3 when overload is applied to or a short circuit occurs in the load side.

The busbars 30 include lead-out busbars 31 drawn out from the main circuit breaker 10 and a plurality of lead-in busbars 33 branched out from the lead-out busbars 31 and entering into the branch circuit breakers 20.

The electric meter 40 measures the electric power consumed by each load and the electric power consumed by the entire loads through each branch circuit breaker 20, detects a short circuit, and calculates electric rates.

The electric meter 40 includes:

a voltage detector 41 detecting voltage at a point where the lead-in busbars 33 are branched out, wherein the lead-in busbars 33 are connected to each branch circuit breaker 20 from the lead-out busbars 31 of the busbars 30;

a current detector 42 detecting a current from a current transformer CT connected to each lead-in busbar 33 of the busbars 30;

a power calculator 44 measuring the power consumed by each load through each branch circuit breaker 20 using the voltage and current detected by the voltage detector 41 and the current detector 42, respectively;

a microcomputer unit MCU 45: analyzing consumed power and electric rates for each load and for total loads, respectively, and whether a short circuit has occurred therein, and so on by receiving the voltage and current detected by the voltage detector 41 and the current detector 42, respectively, and consumed power calculated by the power calculator 44; storing analyzed information in a memory 46; and displaying the information through a monitor 47; and

a communication module 48 transmitting the information on the analyzed power consumption, electric rates, occurrence or nonoccurrence of the short circuit, and so on to an administrator's terminal (for example, a smart phone) by being connected to the microcomputer 45 or allowing the administrator to connect and remotely monitor the information by being connected to the Internet communication network.

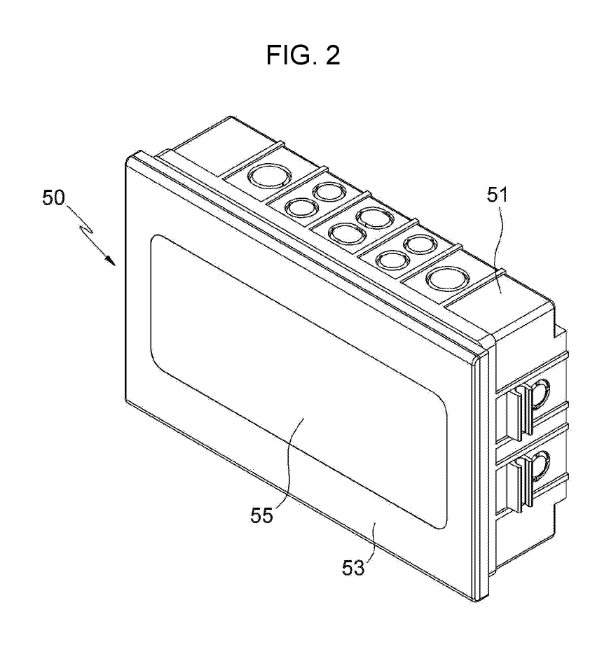

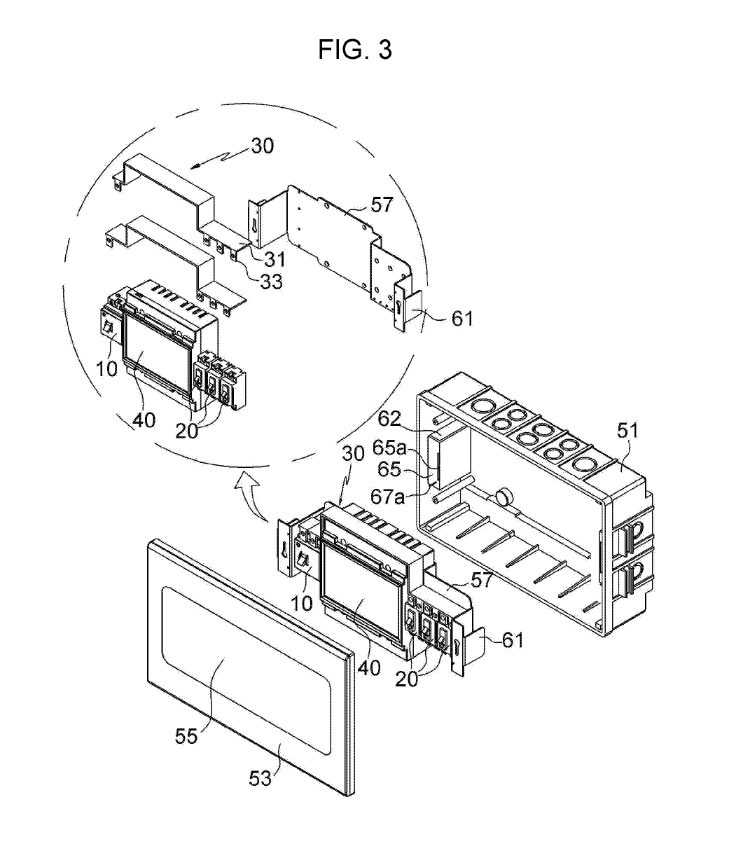

With reference to FIGS. 2 and 3, the enclosure 50 includes a casing 51, a door 53, and a bracket 57.

The casing 51 is equipped with the bracket 57, the main circuit breaker 10, and the like therein, and the door 53 is openably coupled to the opening of the casing 51, wherein the door 53 is provided with a viewing window 55, thereby allowing the inside of the casing 51 to be seen through.

Because the internal space of the casing 51 is narrow, installing or disassembling operation of the main circuit breaker 10, the plurality of branch circuit breakers 20, the electric meter 40, and so on is inconvenient and takes a long time.

Therefore, the present invention introduces the bracket 57, and the main circuit breaker 10, the plurality of branch circuit breakers 20, the electric meter 40, and the like are installed on the bracket 57 outside the casing 51, thereby allowing the bracket 57 to be easily coupled to the inside of the casing 51 through the engaging device 60.

The bracket 57 is formed in a U-shaped cross section, and equipped with the main circuit breaker 10, the plurality of branch circuit breakers 20, and the electric meter 40, wherein the main circuit breaker 10 and the plurality of branch circuit breakers 20 are connected by the busbars 30.

The engaging device 60 allows the bracket 57 to be easily engaged with and detached from the casing 51 without fastening tools such as a screwdriver, a bolt, and the like.

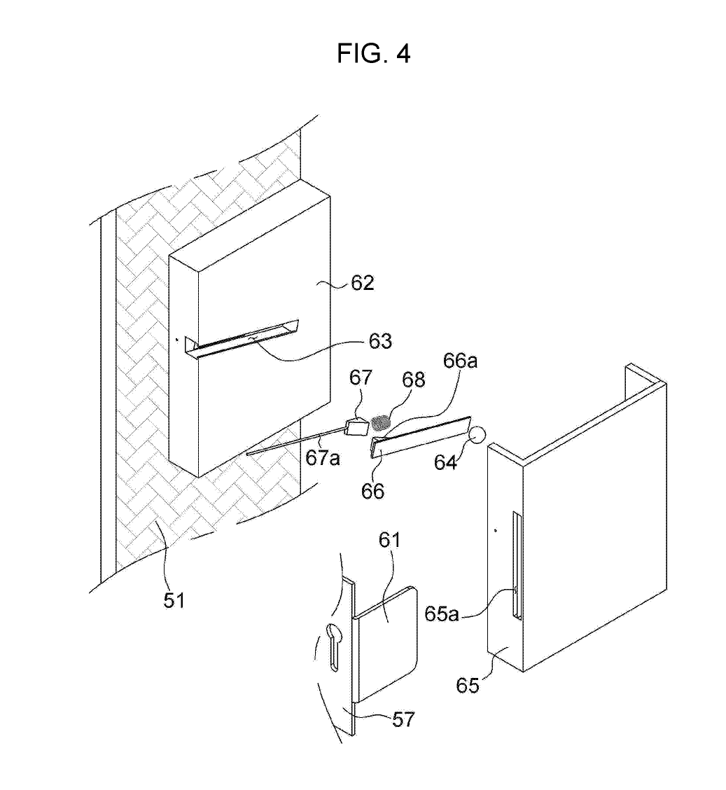

With reference to FIG. 4, the engaging device 60 includes:

an engaging plate 61 provided on both sides of the bracket 57 in the forward and backward directions;

an engaging block 62 coupled to both side inner walls of the casing 51;

a guide groove 63 foiled in the front and rear directions on the surface of the engaging block 62;

a depth adjustment plate 66 disposed at the bottom of the guide groove 63 and adjusting the depth of the guide groove 63 to become deeper toward the rear;

an engaging ball 64 moving along the guide groove 63; and

a cover 65 covering the engaging block 62.

It is preferable that the guide groove 63 has a front side positioned lower than the rear side thereof, thereby allowing the engaging ball 64 located in the guide groove 63 to be moved forward by its own weight.

The cover 65 is formed with an insertion hole 65a through which the engaging plate 61 is inserted and moved in the front and rear directions. In addition, the cover 65 covers the engaging block 62 to be spaced apart by a predetermined distance therefrom, thereby allowing the engaging plate 61 to be inserted into the space provided between the cover 65 and the engaging block 62 and preventing the engaging ball 64 from being separated and detached from the guide groove 63.

A sloped inclined-portion 66a protrudes from and is formed on the inner surface of the front side of the depth adjustment plate 66, and an inclined block 67 having an inclined plane corresponding to the inclined plane of the inclined-portion 66a is seated movably in front and rear directions at a forward-backward groove 63a formed on the bottom of the guide groove 63.

The inclined block 67 is elastically supported from the rear thereof by a spring 68 in the forward-backward groove 63a and normally pushes the inclined portion 66a by being moved forward. Thus, the front side of the depth adjustment plate 66 is raised from the bottom of the guide groove 63, whereby the guide groove 63 increases in depth in a direction from the front to the rear.

A lever 67a is connected to the front of the inclined block 67 and exposed passing through the engaging block 62 and the cover 65. When the exposed lever 67a is pressed, the inclined block 67 is moved backward in the forward-backward groove 63a, thereby allowing the front side of the depth control plate 66 to be lowered to the bottom.

The engaging ball 64 and the engaging plate 61 preferably have a strong frictional force, whereby engagement by the engaging ball 64 is prevented from being arbitrarily released.

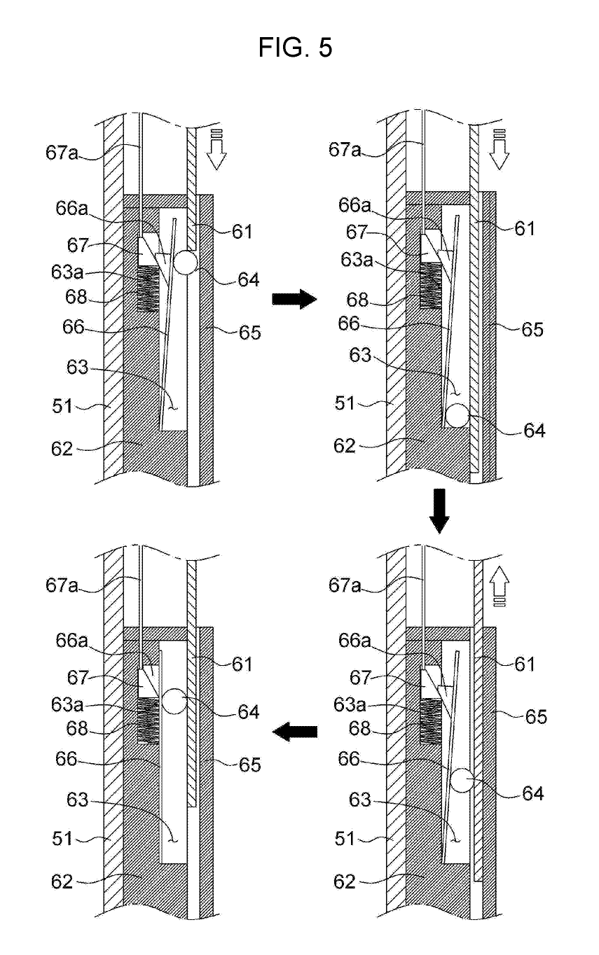

The process of coupling and separating the bracket 57 and the casing 51 through the engaging device 60 composed as described above will be described with reference to FIG. 5.

When the bracket 57 is engaged with the casing 51, first, the engaging plate 61 of the bracket 57 is inserted into the insertion hole 65a of the cover 65 and pushed.

With reference to a first drawing of FIG. 5, the engaging plate 61 inserted into the insertion hole 65a enters into a gap between the engaging block 62 and the cover 65 and moves rearward, and the engaging ball 64 comes into contact with and is pushed rearward by the end of the engaging plate 61 moving rearward, wherein, with reference to a second drawing of FIG. 5, as the guide groove 63 has a depth becoming deeper toward the rear, the engaging ball 64 moves reward along the guide groove 63 without particular resistance, whereby movement of the engaging plate 61 is allowed.

The engaging plate 61 is moved rearward further beyond the engaging ball 64 while the engaging ball 64 is stopped at the rear end of the guide groove 63.

When the movement of the engaging plate 61 in a rearward direction is completed, the engaging ball 64 moves forward along the guide groove 63 due to its own weight and stops at a position where it contacts with the engaging plate 61.

With reference to a third drawing of FIG. 5, when the bracket 57 is pulled, that is, when the engaging plate 61 is moved forward, the engaging ball 64 moves forward along the guide groove 63 by the frictional force. Since the guide groove 63 has a depth decreasing in a forward direction, when the engaging ball 64 moving forward presses and pushes the engaging plate 61, the engaging plate 61 being pushed presses the cover 65 and is brought into close contact therewith. As the engaging ball 64 moves closer to the front of the guide groove 63, the pressing force becomes stronger.

As described above, the engaging plate 61 is inserted into a gap between the engaging block 62 and the cover 65 through the input hole 65a without particular resistance, thereby coupling the bracket 57 and the casing 51 to each other. In a state when coupling is completed, when the engaging plate 61 is even slightly displaced from the insertion hole 65a, the engaging ball 64 strongly presses the engaging plate 61, thereby preventing the engaging plate 61 from being detached and separated.

When the bracket 57 is to be separated from the casing 51, the lever 67a is pressed and the bracket 57 is pulled out.

With reference to a fourth drawing of FIG. 5, when the lever 67a is pressed, the front side of the depth adjustment plate 66 is lowered, thereby causing the front side depth of the guide groove 63 to be deepened. Accordingly, the engaging ball enters into the guide groove 63 and leaves the engaging plate 61 not to be pressed, whereby the engaging plate 61 is separated without particular resistance.

While the power distribution box equipped with a busbar integrated electric meter having the specific configuration and structure has been described with reference to the accompanying drawings for the description of the present invention, it is to be understood that the present invention has been described in connection with what is presently considered to be various modifications and variations. Accordingly, those various modifications and variations should be construed as falling within the scope of protection of the present invention.

What is claimed is:

1. A power distribution box equipped with a busbar integrated electric meter, the power distribution box comprising:
a main circuit breaker connected to lead-in power supply lines to which commercial power is supplied;
a plurality of branch circuit breakers connected to power supply branch lines connected to respective loads;
busbars including lead-out bars drawn out from the main circuit breaker, and a plurality of lead-in bars branched out from the lead-out bars and entering into the plurality of branch circuit breakers, respectively; and
an electric meter measuring power applied to each of the plurality of branch circuit breakers through each of the lead-in bars of the busbars.

2. The power distribution box of claim 1, further comprising:
a bracket mounted with the main circuit breaker, the branch circuit breakers, and the electric meter;
a casing enclosing the bracket,
a door openably covering an opening of the casing; and
an enclosure including a transparent window provided on the door and allowing the inside of the casing to be seen therethrough.

3. The power distribution box of claim 2, further comprising:
an engaging plate provided on both sides of the bracket in forward and backward directions;
an engaging block coupled to both side inner walls of the casing;
a guide groove formed in front and rear directions on a surface of the engaging block and becoming deeper toward the rear;
an engaging ball moving along the guide groove;
a cover covering the engaging block; and
an engaging device that is operated such that when the engaging plate enters into a gap between the engaging block and the cover and moves rearward, the engaging ball is brought into contact with the engaging plate and pushed rearward along the guide groove, thereby allowing the engaging plate to advance, and when the engaging plate moves forward, the engaging ball brought into contact with the engaging plate moves forward along the guide groove, thereby allowing the engaging plate not to move backwards by pressing a surface of the engaging plate.
